(19) United States
(12) Patent Application Publication
(10) Pub. No.: US 2024/0317492 A1
(43) Pub. Date: Sep. 26, 2024

(54) DISTRIBUTION STORAGE SYSTEM

(71) Applicant: Samsung Electronics Co., Ltd., Suwon-si (KR)

(72) Inventors: Junhyuk CHANG, Suwon-si (KR); Seunggyu KANG, Suwon-si (KR); Hyunjae KANG, Suwon-si (KR); Sangmin KIM, Suwon-si (KR); Youngwook KIM, Suwon-si (KR); Jaesung BYUN, Suwon-si (KR); Yongjun AHN, Suwon-si (KR); Sangkyung LEE, Suwon-si (KR); Hyunwoo LEE, Suwon-si (KR); Jeonghun LIM, Suwon-si (KR)

(73) Assignee: Samsung Electronics Co., Ltd., Suwon-si (KR)

(21) Appl. No.: 18/612,401

(22) Filed: Mar. 21, 2024

(30) Foreign Application Priority Data
Mar. 24, 2023 (KR) 10-2023-0039221
May 18, 2023 (KR) 10-2023-0064563

(51) Int. Cl. B65G 1/04

(52) U.S. Cl. CPC B65G 1/0457; B65G 2201/0297

(57) ABSTRACT

A distribution storage system including a wall protruding from a floor in a vertical direction and extending in a first horizontal direction, a plurality of shelves positioned adjacent to a side of the wall and having a space in which carriers are accommodated, an interface port positioned adjacent to a lowermost shelf among the plurality of shelves, a first rail positioned near a ceiling to face the interface port in the vertical direction and extending in the first horizontal direction, a crane moving along the first rail, and a transfer robot coupled to the crane, driven in the vertical direction, and gripping and releasing the carriers, wherein the plurality of shelves are all arranged on one plane.

### CROSS-REFERENCE TO RELATED APPLICATION

This application is based on and claims priority under 35 U.S.C. § 119 to Korean Patent Application Nos. 10-2023-0039221, filed on Mar. 24, 2023, and 10-2023-0064563, filed on May 18, 2023 in the Korean Intellectual Property Office, the disclosures of which are incorporated by reference herein in their entirety.

### BACKGROUND

Inventive concepts relate to a distribution storage system, and more particularly, to a distribution storage system formed adjacent to a wall.

In a semiconductor production site, a plurality of substrates completed through various processes are accommodated in carriers to improve (e.g., increase and/or maximize) work efficiency and increase cleanliness.

The carriers for accommodating the plurality of substrates are loaded into the distribution storage system, or unloaded from the distribution storage system. The research on minimizing the space in a fabrication (FAB) occupied by the distribution storage system in which the carriers are stored and efficiently storing the carriers is ongoing.

### SUMMARY

Various inventive concepts provide a distribution storage system which utilizes the idle space around a wall to store carriers.

In addition, various inventive concepts are not limited to the mentioned above, and other inventive concepts may be clearly understood by those skilled in the art from the description below.

Example embodiments of inventive concepts provide a distribution storage system including a wall protruding from a floor in a vertical direction and extending in a first horizontal direction, a plurality of shelves positioned adjacent to a side of the wall and having a space in which carriers are accommodated, an interface port positioned adjacent to a lowermost shelf among the plurality of shelves, a first rail positioned near a ceiling to face the interface port in the vertical direction and extending in the first horizontal direction, a crane configured to move along the first rail, and a transfer robot coupled to the crane, the transfer robot configured to be driven in the vertical direction, and further configured to grip and release the carriers, wherein the plurality of shelves are all arranged on one plane.

Example embodiments of inventive concepts provide a distribution storage system including a wall protruding from a floor in a vertical direction and extending in a first horizontal direction, a storage unit arranged adjacent to a side of the wall, and including a plurality of shelves having spaces for accommodating carriers and a frame coupled to each of the plurality of shelves, a lower support located under the plurality of shelves and supporting the plurality of shelves, a first support located on top of the frame and supporting the load of the storage unit, an interface port positioned adjacent to a lowermost shelf among the plurality of shelves, a first rail positioned near a ceiling to face the interface port in the vertical direction and extending in the first horizontal direction, a crane configured to move along the first rail, and a transfer robot coupled to the crane, the transfer robot configured to be driven in the vertical direction, and further configured to grip and release the carriers, wherein the plurality of shelves are all arranged on one plane, and wherein an empty space is provided inside the lower support.

Example embodiments of inventive concepts provide a distribution storage system including a wall protruding from a floor in a vertical direction and extending in a first horizontal direction, columns on both sides of the wall in the first horizontal direction, a storage unit arranged adjacent to a side of the wall, and including a plurality of shelves having spaces for accommodating carriers and a frame coupled to each of the plurality of shelves, a lower support located under the plurality of shelves and supporting the plurality of shelves, a first support located on top of the frame and supporting the load of the storage unit, an interface port positioned adjacent to a lowermost shelf among the plurality of shelves, a first rail positioned near a ceiling to face the interface port in the vertical direction and extending in the first horizontal direction, a crane configured to move along the first rail, a transfer robot coupled to the crane, the transfer robot configured to be driven in the vertical direction, and further configured to grip and release the carriers, a second rail spaced apart from the wall in a second horizontal direction with the first rail therebetween and extending in the first horizontal direction, and an overhead hoist transfer device configured to move along the second rail, wherein the plurality of shelves are all arranged on one plane, the carriers are configured to accommodate wafers, and the plurality of shelves, the first rail, the crane, and the transfer robot do not protrude beyond the sides of the columns in the second horizontal direction, and an empty space is provided inside the lower support.

### BRIEF DESCRIPTION OF THE DRAWINGS

Example embodiments will be more clearly understood from the following detailed description taken in conjunction with the accompanying drawings in which:

FIG. 1 is a schematic perspective view of a distribution storage system according to an example embodiment;

FIG. 2 is a schematic cross-sectional view of the distribution storage system of FIG. 1;

FIG. 3A is a schematic perspective view of a first rail, a crane, and a transfer robot;

FIG. 3B is a schematic perspective view of the first rail of FIG. 3A;

FIG. 3C is a schematic perspective view of the crane, and the transfer robot of FIG. 3A;

FIGS. 4A and 4B are schematic perspective views of a storage unit of FIG. 1;

FIG. 5 is a schematic perspective view of a distribution storage system according to an example embodiment;

FIGS. 6A to 6C are schematic diagrams for illustrating an operation of loading a carrier into a distribution storage system according to an example embodiment; and

FIGS. 7A to 7C are schematic diagrams for illustrating an operation of unloading a carrier from a distribution storage system according to an example embodiment.

### DETAILED DESCRIPTION

Hereinafter, example embodiments will be described in detail with reference to the accompanying drawings. The same reference numerals are used for the same components in the drawings, and duplicate descriptions thereof are omitted.

It will be understood that when an element such as a layer, film, region, or substrate is referred to as being “on” another element, it may be directly on the other element or intervening elements may also be present. In contrast, when an element is referred to as being “directly on” another element, there are no intervening elements present. It will further be understood that when an element is referred to as being “on” another element, it may be above or beneath or adjacent (e.g., horizontally adjacent) to the other element.

It will be understood that elements and/or properties thereof (e.g., structures, surfaces, directions, or the like), which may be referred to as being “parallel,” or the like with regard to other elements and/or properties thereof (e.g., structures, surfaces, directions, or the like) may be “perpendicular,” “parallel,” or the like or may be “substantially perpendicular,” “substantially parallel,” respectively, with regard to the other elements and/or properties thereof.

When the terms “about” or “substantially” are used in this specification in connection with a numerical value, it is intended that the associated numerical value include a tolerance of ±10% around the stated numerical value. When ranges are specified, the range includes all values therebetween such as increments of 0.1%.

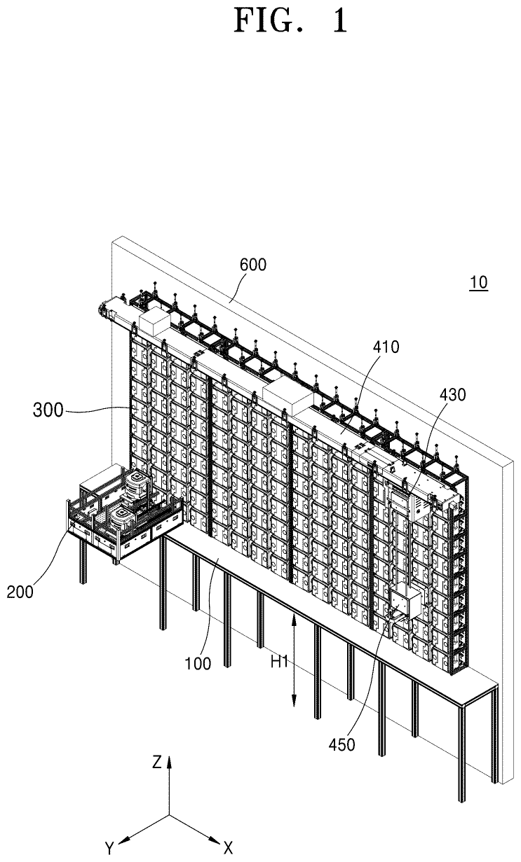

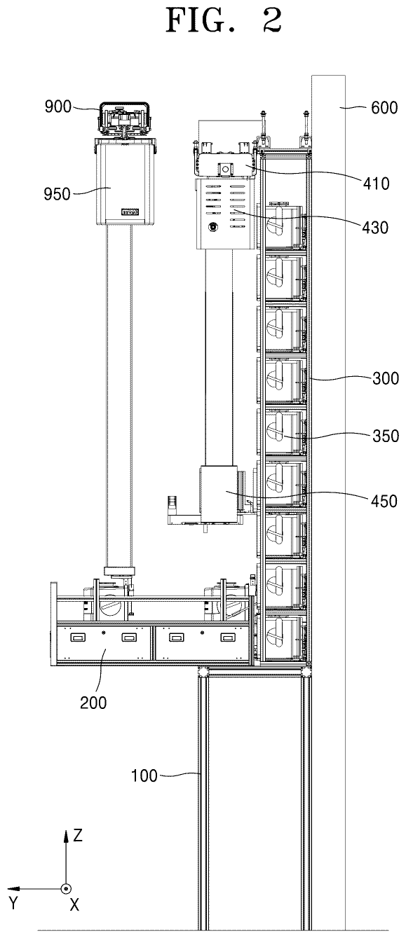

FIG. 1 is a schematic perspective view of a distribution storage system according to an example embodiment. FIG. 2 is a schematic cross-sectional view of the distribution storage system of FIG. 1.

Referring to FIGS. 1 and 2, a distribution storage system 10 may include a wall 600, a lower support 100, a storage unit 300, an interface port 200, a first rail 410, a crane 430, and a transfer robot 450.

The wall 600 may protrude from a floor in a vertical direction Z and may extend in a first horizontal direction X. The first horizontal direction X represents an example embodiment of a direction in which the wall 600 extends, and the direction in which the wall 600 extends is not limited to the first horizontal direction X. According to some example embodiments, the wall 600 may be a wall formed inside a semiconductor FAB. For example, the wall 600 may be formed to divide an area inside the semiconductor FAB or to support the load of a ceiling.

According to some example embodiments, the wall 600 may protrude from the floor to the ceiling in the vertical direction Z. However, the wall 600 is not limited thereto. The wall 600 may extend only up to a certain height in the vertical direction Z from the floor and may not extend up to the ceiling. According to some example embodiments, the height in the vertical direction Z from the floor to the ceiling may be in a range of about 4 m to about 5 m but is not limited thereto.

The wall 600 may have sides perpendicular to the floor. According to some example embodiments, the lower support 100 and the storage unit 300 may be formed adjacent to a side having the largest cross-sectional area among the sides of the wall 600.

The lower support 100 may be configured to support the storage unit 300. According to some example embodiments, the lower support 100 may be located adjacent to a side of the wall 600. The lower support 100 may be placed in contact with the side of the wall 600.

According to some example embodiments, an empty space may be formed inside the lower support 100. The empty space may be formed under the lower support 100 supporting the storage unit 300. For example, the lower support 100 may include a plurality of legs extending in the vertical direction Z, and a flat plate coupled to an upper surface of each of the legs and extending in the first horizontal direction. The flat plate may contact the lower surface of the storage unit 300. An empty space may be formed under the flat plate. Under the flat plate, an empty space formed between the plurality of legs may be formed by a first height H1 in the vertical direction Z.

According to some example embodiments, the first height H1 may be in a range of about 2 m to about 2.5 m. Infrastructures may be formed near the wall 600 formed inside the FAB. The infrastructures may include, for example, electrical panels, lighting, fire extinguishers, air ducts, and the like. The infrastructures may be formed up to about 2 m from the floor. In some example embodiments, when the first height H1 of the empty space formed inside the lower support 100 is in a range of about 2 m to about 2.5 m, the distribution storage system 10 may be installed without demolition of the infrastructures. For example, it may be possible to utilize the distribution storage system 10 that does not occupy the floor area of the FAB while continuously using the infrastructures. In addition, in some example embodiments, even when the infrastructures are not formed, the empty space formed in the lower support 100 may function as a passage through which people pass.

In some example embodiments, the storage unit 300 may be located on top of the lower support 100. However, the storage unit 300 is not limited thereto. In some example embodiments, the storage unit 300 may be formed on the floor. In some example embodiments, when the infrastructures are not formed on a side of the wall 600, the storage unit 400 may be directly on the floor.

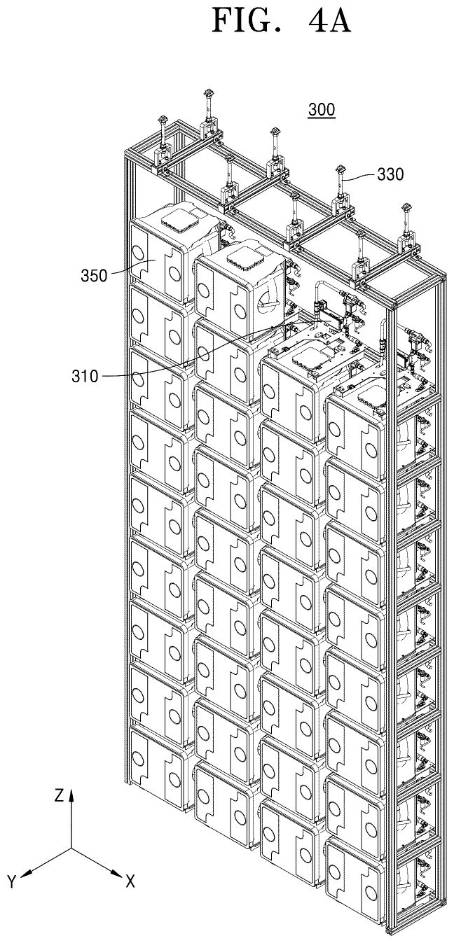

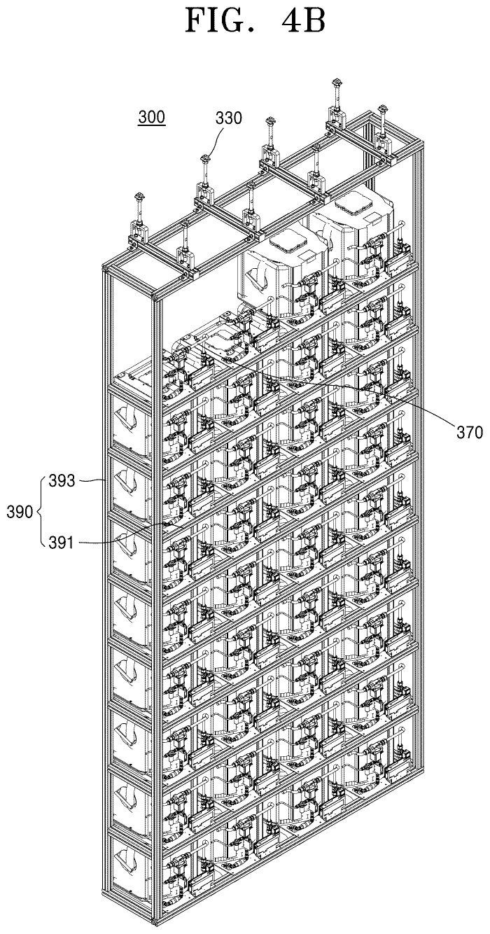

The storage unit 300 may be in contact with a side of the wall 600. In other words, the storage unit 300 may be positioned adjacent to a side of the wall 600. The storage unit 300 may be configured to store a carrier 350. Detailed components of the storage unit 300 are described below with reference to FIGS. 4A and 4B. The storage unit 300 may store a plurality of carriers 350.

According to some example embodiments, all of the plurality of carriers 350 may be stored in one plane in the storage unit 300. For example, the plurality of carriers 350 stored in the storage unit 300 may be arranged in a line along the Y-Z plane. Accordingly, the plurality of carriers 350 stored in the storage unit 300 may overlap each other in the vertical direction Z or the first horizontal direction X. The plurality of carriers 350 stored in the storage unit 300 may not overlap each other in the second horizontal direction Y. In other words, the plurality of carriers 350 stored in the storage unit 300 may not face each other in the second horizontal direction Y.

According to some example embodiments, the carrier 350 may be configured to store wafers. The carrier 350 may be a container for accommodating semiconductor substrates such as wafers. The carrier 350 may include a sealed container for protecting substrates from foreign substances or chemical contamination in the air.

The carrier 350 may include a body having an open space on one side and a door that opens and closes the body. A plurality of slots into which portions of the edge of the substrate are inserted may be provided in the inner wall of the body. The slots may be provided in the inner wall of the body while being spaced apart in the vertical direction Z at certain intervals. The body may have a material and/or structure optimized for extreme cleanliness. A plate spring may be installed on an inner wall of the door to apply certain pressure to the substrates loaded in the carrier 350 when the door is closed.

In some example embodiments, the carrier 350 may include a front opening unified pod (FOUP). However, the carrier 350 is not limited thereto. The carrier 350 suffices as long as the carrier 350 is a container capable of storing goods.

The interface port 200 may be positioned adjacent to the lowermost end of the storage unit 300. The interface port 200 may be spaced apart from the wall 600 in the second horizontal direction Y with the storage unit 300 therebetween.

The interface port 200 may be a space where the carrier 350 rests before the carrier 350 stored in the storage unit 300 is unloaded from the storage unit 300 and before the carrier 350 is loaded into the storage unit 300. For example, the carrier 350 may be loaded into the interface port 200 by an overhead hoist transfer device 950, and the carrier 350 loaded in the interface port 200 may be transferred to the storage unit 300 by the transfer robot 450. In addition, on the contrary, the carrier 350 stored in the storage unit 300 may be loaded into the interface port 200 by the transfer robot 450, and the carrier 350 loaded in the interface port 200 may be unloaded by the overhead hoist transfer device 950.

According to some example embodiments, the interface port 200 may include a loading unit where the carrier 350 is loaded and an unloading unit where the carrier 350 is unloaded. Each of the loading unit and the unloading unit may include a conveyor belt. The carrier 350 placed on the interface port 200 by the conveyor belt may move back and forth in the second horizontal direction Y.

According to some example embodiments, the carrier 350 transferred to the interface port 200, specifically the unloading unit of the interface port 200, from the storage unit 300 may be positioned close to the storage unit 300 and may move away from the storage unit 300 in the second horizontal direction Y through the conveyor belt. The moved carrier 350 may be gripped and transferred outside the distribution storage system 10 by the overhead hoist transfer device 950.

On the contrary, the carrier 350 transferred from the overhead hoist transfer device 950 to the interface port 200, specifically the loading unit of the interface port 200, may be positioned far from the storage unit 300 and may move in the second horizontal direction Y to approach the storage unit 300 through the conveyor belt. The moved carrier 350 may be gripped and transferred to the storage unit 300 by the transfer robot 450.

The first rail 410 may be spaced apart from the wall 600 in the second horizontal direction Y with the storage unit 300 therebetween. The first rail 410 may be positioned adjacent to the storage unit 300. The first rail 410 may be positioned close to the ceiling. The first rail 410 may face the interface port 200 in the vertical direction Z. According to some example embodiments, the first rail 410 may be fixed through frames formed on the ceiling. The first rail 410 may extend in the first horizontal direction X.

The crane 430 may be coupled to the first rail 410. According to some example embodiments, the crane 430 may be coupled to the first rail 410 at a lower portion of the first rail 410. For example, the crane 540 may be positioned at the lower portion of the first rail 410.

The crane 430 may be driven along the first rail 410. In other words, the crane 430 may move in the first horizontal direction X. According to some example embodiments, the crane 430 may include a pair of wheels. The pair of wheels may rotate along the first rail 410.

The transfer robot 450 may be coupled to the crane 430. According to some example embodiments, the transfer robot 450 may be coupled to a lower portion of the crane 430. The transfer robot 450 may be configured to transfer the carrier 350. The transfer robot 450 may be configured to grip and release the carrier 350. The transfer robot 450 may be driven in the vertical direction Z. In some example embodiments, the transfer robot 450 may be coupled to the crane 430 by a hoist and may be moved closer to or farther away from the crane 430 in the vertical direction Z by the hoist. For example, the transfer robot 450 may be driven in the vertical direction Z with respect to the crane 430.

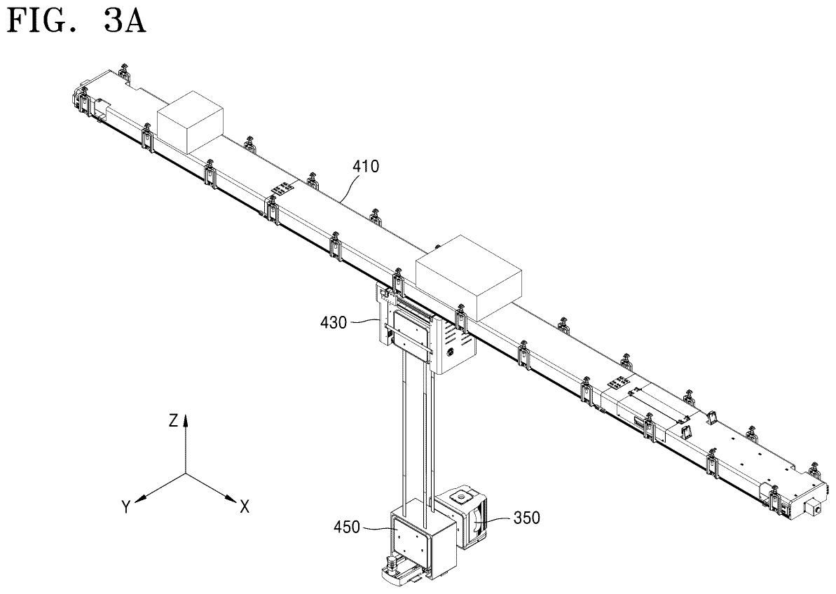

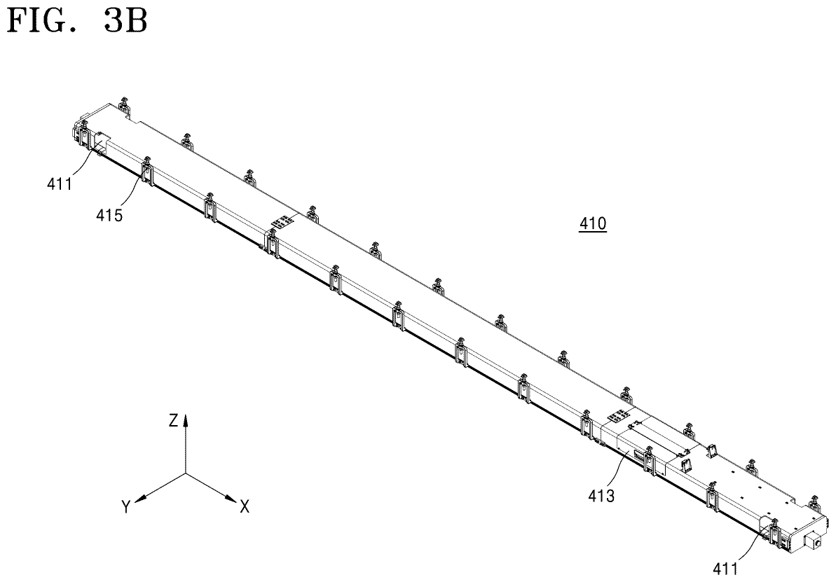

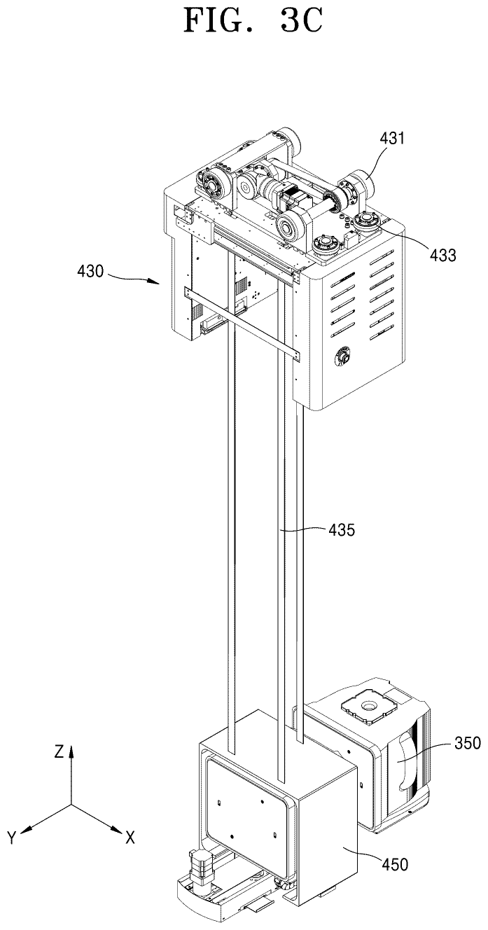

According to some example embodiments, the transfer robot 450 may grip the carrier 350 stored in the storage unit 300 and separate the carrier 350 from the storage unit 300. In addition, in some example embodiments, the transfer robot 450 may release the carrier 350 to the interface port 200. A detailed description of the first rail 410, the crane 430, and the transfer robot 450 is described below with reference to FIGS. 3A to 3C.

A second rail 900 may be spaced apart from the first rail 410 in the second horizontal direction Y with the storage unit 300 therebetween. The second rail 900 may extend in the first horizontal direction X. According to some example embodiments, an empty space may be formed between the first rail 410 and the second rail 900 in the second horizontal direction Y. For example, the second rail 900 may be spaced apart from the first rail 410 in the second horizontal direction Y at certain intervals.

According to some example embodiments, the second rail 900 may be configured to provide a conveyance path for conveying items between manufacturing facilities, between manufacturing facilities and the distribution storage systems 10, or between the distribution storage systems 10. The second rail 900 may provide a path for the overhead hoist transfer device 950 and may have a different shape depending on the arrangement of manufacturing facilities.

The overhead hoist transfer device 950 may be coupled to the second rail 900. According to some example embodiments, the overhead hoist transfer device 950 may be coupled to the second rail 900 at a lower portion of the second rail 900. The overhead hoist transfer device 950 may be configured to transport the carrier 350. The overhead hoist transfer device 950 may load the carrier 350 into the interface port 200 or grip and lift the carrier 350 loaded in the interface port 200 upward in the vertical direction Z.

In the distribution storage system 10 according to an example embodiment, the storage unit 300 may be positioned adjacent to the wall 600. In addition, in some example embodiments, the carriers 350 stored in the storage unit 300 may be arranged in one line along the Y-Z plane. For example, all of the carriers 350 may be positioned adjacent to the wall 600. Accordingly, the space occupied by the distribution storage system 10 in the FAB may be minimized. The carriers 350 may be loaded into the storage unit 300 through a side opposite to the side facing the wall 600 in the storage unit 300, and, on the contrary, the carriers 350 stored in the storage unit 300 may be unloaded from the storage unit 300 through a side opposite to the side facing the wall 600. In addition, in some example embodiments, the first rail 410, the crane 430, and the transfer robot 450 may be located to the second horizontal direction Y of the storage unit 300 in order from the top of the storage unit 300 to load and unload the carrier 350, and the carrier 350 loaded in the interface port 200 may be transferred to the storage unit 300 through the first rail 410, the crane 430, and the transfer robot 450. In addition, in some example embodiments, the carrier 350 stored in the storage unit 300 may be transferred to the interface port 200 through the first rail 410, the crane 430, and the transfer robot 450.

Therefore, compared to a stocker in which carriers 350 are stored in two or more lines along the Y-Z plane, the area occupied by the distribution storage system 10 in the FAB may be reduced by more than half. In addition, in some example embodiments, as the distribution storage system 10 is formed in the space near the wall 600, which can be understood as an idle space, the space inside the FAB may be used more efficiently.

Furthermore, the distribution storage system 10 may further include the lower support 100, and an empty space may be formed under the lower support 100. The empty space may have a volume capable of accommodating infrastructures installed near the wall 600, and accordingly, the distribution storage system 10 may be formed without removing existing infrastructures installed near the wall 600.

In some example embodiments, as described below, since the storage unit 300 is fixed through the first support 350 (see FIG. 4B), the distribution storage system 10 may be formed without additional reinforcement of the wall 600.

FIG. 3A is a schematic perspective view of a first rail, a crane, and a transfer robot. FIG. 3B is a schematic perspective view of the first rail of FIG. 3A. FIG. 3C is a schematic perspective view of the crane and the transfer robot of FIG. 3A.

Referring to FIGS. 3A to 3C, a first rail 410 extends in the first horizontal direction X, and a crane 430 may be coupled to the lower portion of the first rail 410. A transfer robot 450 may be coupled to the lower portion of the crane 430, and the transfer robot 450 may move in the vertical direction Z with respect to the crane 430. The transfer robot 450 may be coupled to or separated from the carrier 350.

The first rail 410 may include a wheel replacement area 411, a maintenance area 413, and a second support 415. The wheel replacement area 411 may be a dedicated area for replacing a first wheel 431 located on an upper surface of the crane 430. According to some example embodiments, when replacement of the first wheel 431 of the crane 430 is required, the first wheel 431 may be replaced after exposing the first wheel 431 to the outside of the first rail 410 through the wheel replacement area 411.

The maintenance area 413 may be an area in which repair or maintenance of the crane 430 is performed when repair or maintenance of the crane 430 is required. For example, when repair of the crane 430 is required, repair or maintenance of the crane 430 may be performed after exposing the crane 430 to the outside of the first rail 410 through the maintenance area 413 of the first rail 410.

The second supports 415 may be configured to be coupled with the ceiling. According to some example embodiments, the second support 415 may be coupled with a frame formed on the ceiling. As the second support 415 is coupled to the ceiling or the frame formed on the ceiling, the first rail 410 may be fixed to the ceiling. For example, the second support 415 may support the load of the first rail 410.

According to some example embodiments, a plurality of second supports 415 may be provided, and the plurality of second supports 415 may be arranged side by side spaced apart from each other at certain intervals in the first horizontal direction X.

The crane 430 may include a first wheel 431 and a second wheel 433. The crane 430 may move along the first rail 410 through the first wheel 431 and the second wheel 433. For example, the first wheel 431 and the second wheel 433 may be a means of moving the crane 430. The first wheel 431 may include a motor and a gearbox. The motor may provide power to the gearbox, and the gearbox may convert the power into appropriate torque and rotation speed and provide the power to the first wheel 431. In some example embodiments, the gearbox may be a right angle gearbox.

The first wheel 431 and the second wheel 433 may be provided on the upper surface of the crane 430. The first wheel 431 may directly receive rotational force from the motor and the gearbox. The second wheel 433, which is an auxiliary wheel, may be a steering wheel that changes or maintains the traveling direction of the crane 430.

According to some example embodiments, the transfer robot 450 may be coupled to the crane 430 through a hoist 435. According to some example embodiments, the hoist 435 may include an electric motor, a gearbox, a wire, and a winding drum, but example embodiments are not limited thereto. The wire may be connected to the transfer robot 450. The hoist 435 may move the transfer robot 450 upward in the vertical direction Z by winding up the wire, or may move the transfer robot 450 downward in the vertical direction Z by unwinding the wire. For example, the transfer robot 450 may move in the vertical direction Z by means of the hoist 435.

The transfer robot 450 may be configured to grip or release the carrier 350. In some example embodiments, the transfer robot 450 may fix the carrier 350 inside the transfer robot 450.

FIGS. 4A and 4B are schematic perspective views of a storage unit of FIG. 1. Referring to FIGS. 4A and 4B, a storage unit 300 may include a frame 390, a shelf 310, a first support 330, and a first pipe 370.

The frame 390 may be a frame on which the shelf 310, the first support 330, and the first pipe 370 are installed. The frame 390 may include a first frame 391 and a second frame 393. The first frame 391 may extend in the first horizontal direction X, and the second frame 393 may extend in the vertical direction Z. In some example embodiments, the first frame 391 may have a flat plate shape parallel to the X-Y plane.

According to some example embodiments, four second frames 393 may be provided, and the four second frames 393 may be arranged to form a cuboid shape. For example, a virtual figure connecting three points along the X-Y plane of any three second frames 393 may be a right triangle.

A plurality of first frames 391 may be provided, and the plurality of first frames 391 may be spaced apart from each other at certain intervals in the vertical direction Z. The shelf 310 may be provided above each of the plurality of first frames 391.

The shelf 310 may be arranged to fix the carrier 350. The carrier 350 may be stored on the shelf 310. According to some example embodiments, the shelf 310 may be coupled to the first frame 391. The shelf 310 may include a flat plate supporting the carrier 350 and a fixing member fixing the carrier 350.

According to some example embodiments, a plurality of shelves 310 may be provided. The plurality of shelves 310 may be arranged in a line along the first frame 391. Accordingly, the plurality of shelves 310 coupled to any one first frame 391 may be spaced apart from each other at certain intervals in the first horizontal direction X. As a plurality of first frames 391 may be provided and spaced apart from each other in the vertical direction Z, the shelves 310 coupled to each of the first frames 391 adjacent to each other in the vertical direction Z may also be adjacent to each other in the vertical direction Z.

The plurality of shelves 310 may be exposed to the outside from the frame 390. For example, the shelves 310 may not be sealed by the frame 390.

The plurality of shelves 310 may be arranged on only one plane. For example, the plurality of shelves 310 are adjacent to each other in the vertical direction Z and the first horizontal direction X, and the plurality of shelves 310 are not adjacent to each other in the second horizontal direction Y. In some example embodiments, the plurality of shelves 310 may be arranged in a line on the Y-Z plane.

As the plurality of shelves 310 are arranged on only one plane, the carriers 350 respectively stored on the plurality of shelves 310 are also arranged on only one plane, and since all of the shelves 310 arranged on only one plane are positioned adjacent to the wall 600 (see FIG. 1), the carriers 350 may be stored only in an idle space near the wall 600, thereby improving (e.g., increasing and/or maximizing) space utilization inside the FAB.

The first support 330 may be coupled to the first frame 391 positioned at the top of the frame 390. The first support 330 may extend in the vertical direction Z. The first support 330 may be coupled to the ceiling or a frame formed on the ceiling. Accordingly, the first support 330 may fix the frame 390 to the ceiling or a frame coupled to the ceiling and may support the load of the frame 390.

According to some example embodiments, a plurality of first supports 330 may be provided. The plurality of first supports 330 may be spaced apart from each other at certain intervals on the X-Y plane.

The first pipe 370 may be provided in combination with the shelf 310. The first pipe 370 may be configured to remove fumes and gaseous by-products inside the carrier 350. According to some example embodiments, the fumes and gaseous by-products may be removed by, for example, a purge gas. The purge gas may include, for example, an inert gas. As another example, the purge gas may include nitrogen gas (N₂). A portion of the purge gas may remain inside the carrier 350. The purge gas may be periodically supplied to and exhausted from the carrier 350.

The first pipe 370 may include an exhaust unit and a supply unit. The exhaust unit may be configured to exhaust the purge gas from the carrier 350. Conversely, the supply unit may be configured to supply the purge gas to the carrier 350. The exhaust unit may be connected to a first storage container for recovering the purge gas, and the supply unit may be connected to a second storage container for supplying the purge gas.

The first and second storage containers may be interlocked with first and second flow meters. The first and second flow meters may be electronically controlled. Thus, the flow rates of the first and second storage containers may be controlled.

The storage unit 300 according to various inventive concepts may be framed by the frame 390 and may not be sealed from the outside. Accordingly, the carrier 350 may be easily loaded into the shelf 310 through the first rail 410, the crane 430, and the transfer robot 450 located outside the storage unit 300. In addition, in some example embodiments, since the load of the storage unit 300 is supported by the first support 330, additional reinforcement or construction may be unnecessary for the wall 600 (see FIG. 1).

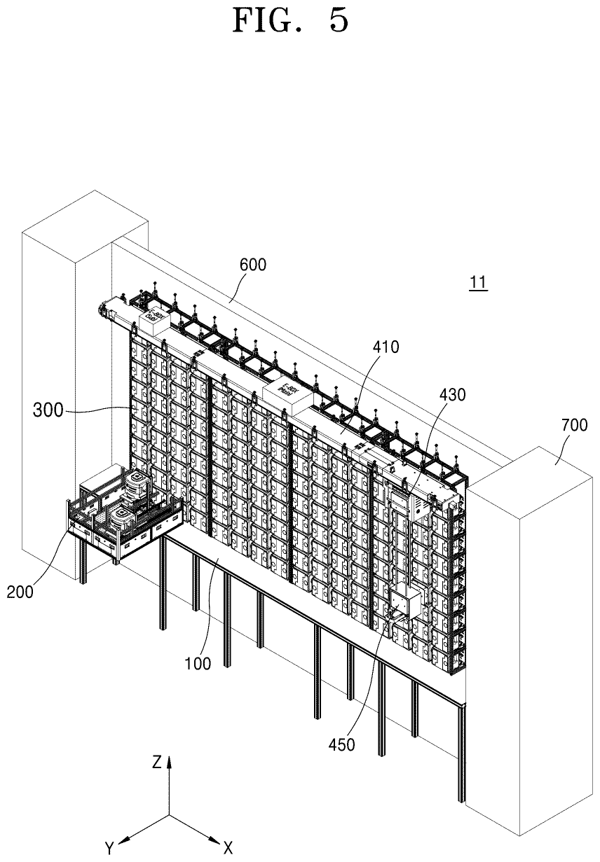

FIG. 5 is a schematic perspective view of a distribution storage system according to an example embodiment. Hereinafter, redundant descriptions of the distribution storage system 10 of FIGS. 1 and 2 and the distribution storage system 11 of FIG. 5 are omitted and the differences therebetween are mainly described.

Referring to FIG. 5, the distribution storage system 11 may include columns 700 formed on sides of the wall 600 in the first horizontal direction X. The columns 700 may be provided on both sides of the wall 600 in the first horizontal direction X.

The columns 700 may have a shape protruding from the floor in the vertical direction Z. The column 700 may extend from the floor to the ceiling. According to some example embodiments, the columns 700 may extend in the second horizontal direction Y and may protrude from the wall 600 in the second horizontal direction Y.

According to some example embodiments, the lower support 100, the storage unit 300, the first rail 410, the crane 430, and the transfer robot 450 may protrude less than the columns 700 in the second horizontal direction Y. For example, the lower support 100, the storage unit 300, the first rail 410, the crane 430, and the transfer robot 450 may be located nearer to the wall 600 than the sides of the columns 700 in the second horizontal direction Y. Accordingly, the distribution storage system 11 may use the idle space near the wall 600 and the columns 700 more efficiently.

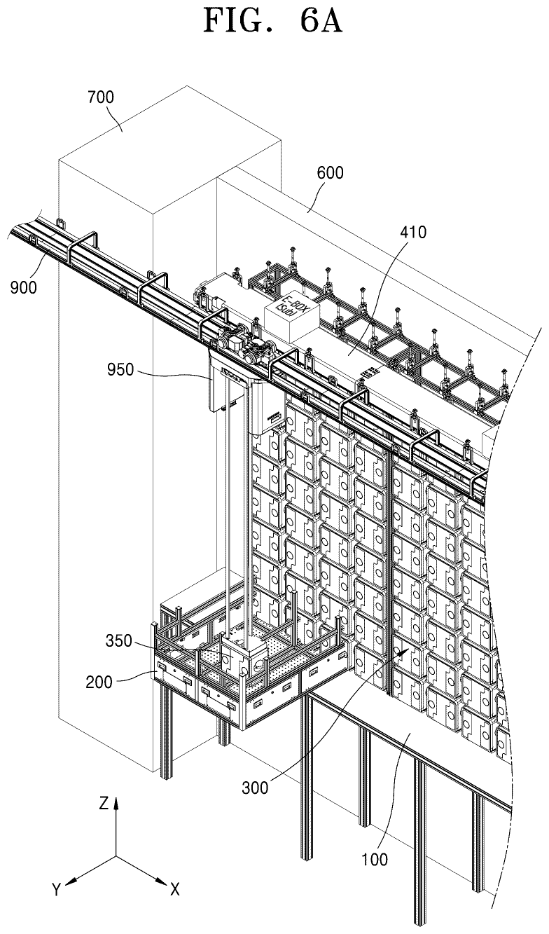

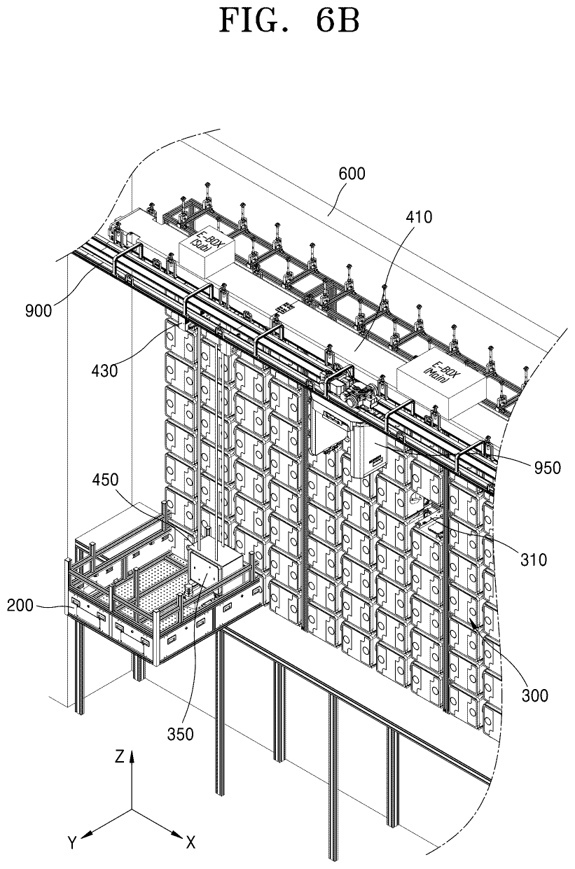

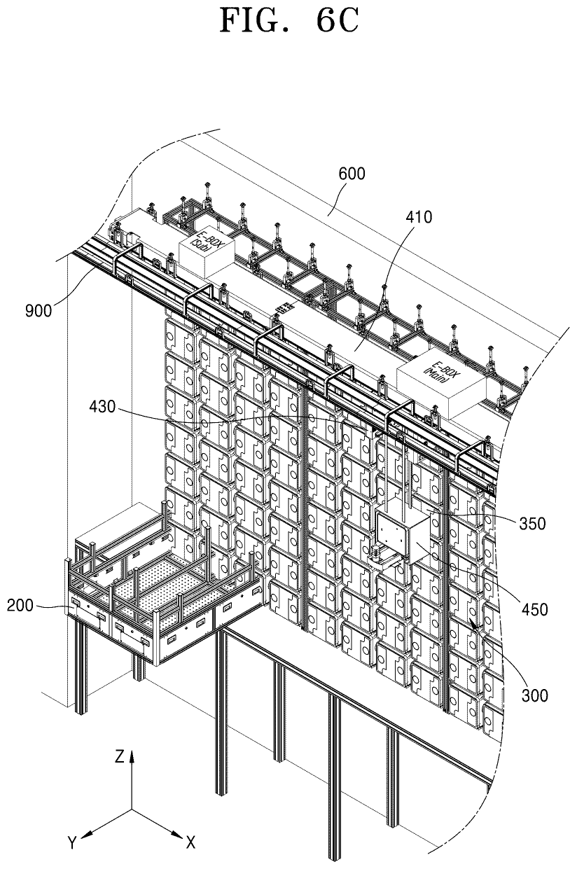

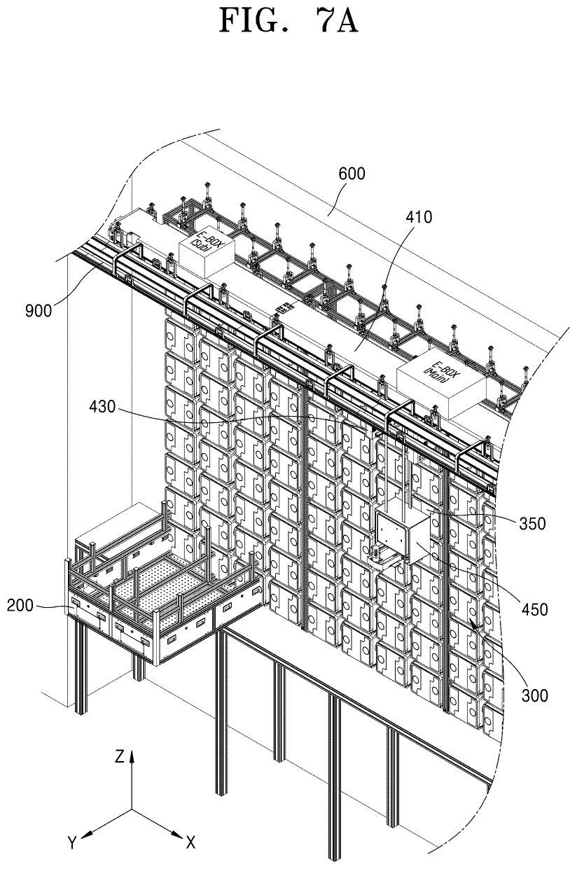

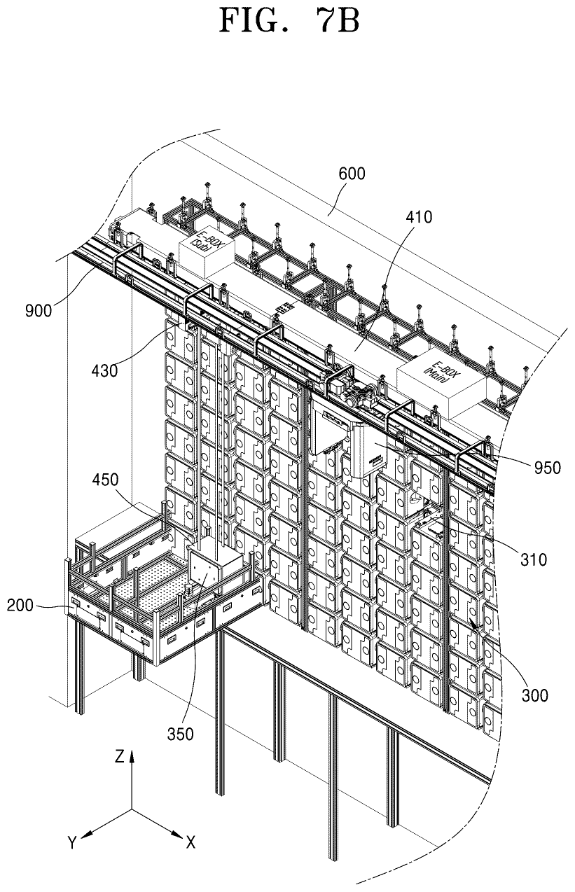

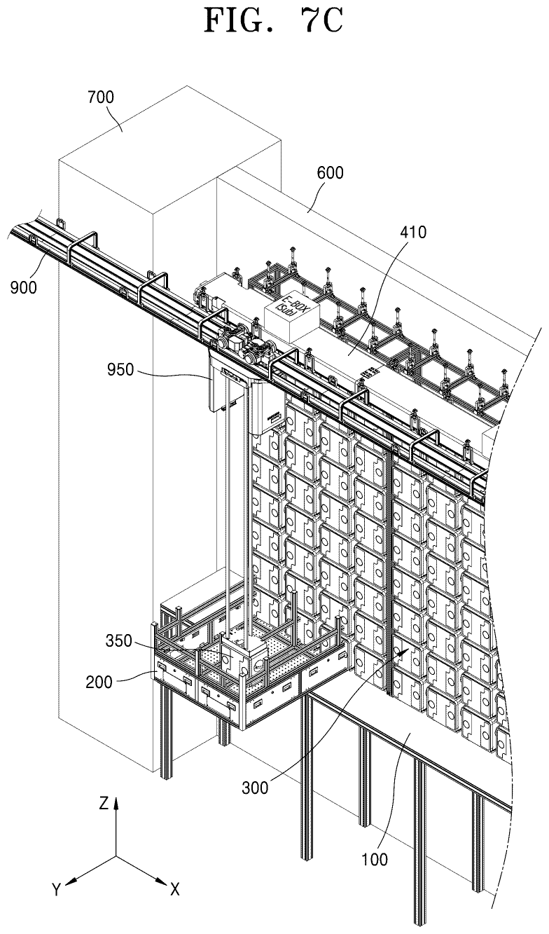

FIGS. 6A to 6C are schematic diagrams for illustrating an operation of loading a carrier into a distribution storage system according to an example embodiment. FIGS. 7A to 7C are schematic diagrams for illustrating an operation of unloading a carrier from a distribution storage system according to an example embodiment.

First, the operation of storing the carrier 350 into the distribution storage system 10 is described. Referring to FIG. 6A, the overhead hoist transfer device 950 moving along the second rail 900 may move while the carrier 350 is accommodated therein. The overhead hoist transfer device 950 may move the carrier 350 to a point where the carrier 350 overlaps with the loading unit of the interface port 200 in the vertical direction Z. The overhead hoist transfer device 950, which moved to the point where the carrier 350 overlaps with the loading unit of the interface port 200 in the vertical direction Z, may move the carrier 350 downward in the vertical direction Z to load the carrier 350 to the loading unit of the interface port 200.

The loaded carrier 350 may move in the second horizontal direction Y through the conveyor belt formed at the interface port 200, wherein the carrier 350 may move closer to the storage unit 300.

Referring to FIG. 6B, the crane 430 may move in the vertical direction Z to a point overlapping the carrier 350, which moved along the first rail 410 in the second horizontal direction Y to approach the storage unit 300. Thereafter, the crane 430 may move the transfer robot 450 downward in the vertical direction Z. After moving to a point adjacent to the carrier 350 located on the interface port 200, the transfer robot 450 may grip the carrier 350.

Referring to FIG. 6C, the carrier 350 gripped by the transfer robot 450 may move in the first horizontal direction X while the crane 430 moves along the first rail 410. The crane 430 may move to the X coordinate where the shelf 310 on which the carrier 350 is not stored is located among the shelves 310 of the storage unit 300. Then, the crane 430 may move the transfer robot 450 in the vertical direction Z to the Z coordinate of the shelf 310.

The transfer robot 450, which moved near the empty shelf 310, may load the carrier 350 onto the shelf 310.

Conversely, the operation of unloading the carrier 350 from the distribution storage system 10 is described. Referring to FIG. 7A, the transfer robot 450 may move near the shelf 310 where the carrier 350 to be unloaded is stored, and then separate the carrier 350 from the shelf 310. The transfer robot 450 gripping the carrier 350 separated from the shelf 310 may move to a point overlapping the unloading unit of the interface port 200 through the first rail 410, and the crane 430. After that, the transfer robot 450 may move downward in the vertical direction Z through the crane 430 and load the carrier 350 into the unloading unit of the interface port 200.

The carrier 350 loaded in the unloading unit of the interface port 200 may be gripped by the overhead hoist transfer device 950, and the overhead hoist transfer device 950 may transfer the carrier 350 to another manufacturing facility or another distribution storage system along the second rail 900.

While various inventive concepts have been particularly shown and described with reference to some example embodiments thereof, it will be understood that various changes in form and details may be made therein without departing from the spirit and scope of the following claims.

What is claimed is:

1. A distribution storage system, comprising:
a wall protruding from a floor in a vertical direction and extending in a first horizontal direction;
a plurality of shelves positioned adjacent to a side of the wall and having a space in which carriers are accommodated;
an interface port positioned adjacent to a lowermost shelf among the plurality of shelves;
a first rail positioned near a ceiling to face the interface port in the vertical direction and extending in the first horizontal direction;
a crane configured to move along the first rail; and
a transfer robot coupled to the crane, the transfer robot configured to be driven in the vertical direction, and further configured to grip and release the carriers,
wherein the plurality of shelves are all arranged on one plane.

2. The distribution storage system of claim 1, further comprising
a second rail spaced apart from the wall in a second horizontal direction with the first rail therebetween and extending in the first horizontal direction, and an overhead hoist transfer device moving along the second rail.

3. The distribution storage system of claim 1,
wherein the carriers are configured to accommodate wafers.

4. The distribution storage system of claim 1,
wherein the crane is connected to the transfer robot by a hoist, and
the transfer robot is driven in the vertical direction by the hoist.

5. The distribution storage system of claim 1, further comprising
a lower support configured to support the plurality of shelves,
wherein an empty space is provided inside the lower support.

6. The distribution storage system of claim 5,
wherein the empty space extends from the floor to a first height in the vertical direction, and
the first height is in a range of about 2 m to about 2.5 m.

7. The distribution storage system of claim 1, further comprising
columns on both sides of the wall in the first horizontal direction.

8. The distribution storage system of claim 7,
wherein the plurality of shelves, the first rail, the crane, and the transfer robot do not protrude beyond the sides of the columns in a second horizontal direction.

9. The distribution storage system of claim 1,
wherein the plurality of shelves are coupled to a frame,
the frame comprises a first frame extending in the horizontal direction and a second frame extending in the vertical direction, and
the plurality of shelves are exposed to outside from the frame.

10. The distribution storage system of claim 9,
wherein the first frame is coupled to a first support, and
the first support is positioned on top of the frame and supports a load of the frame.

11. The distribution storage system of claim 10, further comprising
a first pipe coupled to the shelf and configured to supply a purge gas to the carrier or discharge a purge gas from the carrier.

12. A distribution storage system, comprising:
a wall protruding from a floor in a vertical direction and extending in a first horizontal direction;
a storage unit arranged adjacent to a side of the wall and including a plurality of shelves having spaces for accommodating carriers and a frame coupled to each of the plurality of shelves;
a lower support located under the plurality of shelves and supporting the plurality of shelves;
a first support located on top of the frame and supporting a load of the storage unit;
an interface port positioned adjacent to a lowermost shelf among the plurality of shelves;
a first rail positioned near a ceiling to face the interface port in the vertical direction and extending in the first horizontal direction;
a crane configured to move along the first rail; and
a transfer robot coupled to the crane, the transfer robot configured to be driven in the vertical direction, and further configured to grip and release the carriers,
wherein the plurality of shelves are all arranged on one plane, and
wherein an empty space is provided inside the lower support.

13. The distribution storage system of claim 12,
wherein the lower support comprises a plurality of legs extending in the vertical direction and a flat plate positioned on top of the plurality of legs.

14. The distribution storage system of claim 13,
wherein the empty space extends from the floor to a first height in the vertical direction, and
the first height is in a range of about 2 m to about 2.5 m.

15. The distribution storage system of claim 12, further comprising
columns on both sides of the wall in the first horizontal direction,
wherein the plurality of shelves, the first rail, the crane, and the transfer robot do not protrude beyond the sides of the columns in a second horizontal direction.

16. The distribution storage system of claim 12, further comprising
a second rail spaced apart from the wall in a second horizontal direction with the first rail therebetween and extending in the first horizontal direction, and an overhead hoist transfer device configured to move along the second rail.

17. The distribution storage system of claim 12,
wherein the carriers are configured to accommodate wafers.

18. A distribution storage system, comprising:
a wall protruding from a floor in a vertical direction and extending in a first horizontal direction;
columns on both sides of the wall in the first horizontal direction;
a storage unit arranged adjacent to a side of the wall and including a plurality of shelves having spaces for accommodating carriers and a frame coupled to each of the plurality of shelves;
a lower support located under the plurality of shelves and supporting the plurality of shelves;
a first support located on top of the frame and supporting a load of the storage unit;
an interface port positioned adjacent to a lowermost shelf among the plurality of shelves;
a first rail positioned near a ceiling to face the interface port in the vertical direction and extending in the first horizontal direction;
a crane configured to move along the first rail;
a transfer robot coupled to the crane, the transfer robot configured to be driven in the vertical direction, and further configured to grip and release the carriers;
a second rail spaced apart from the wall in a second horizontal direction with the first rail therebetween and extending in the first horizontal direction; and
an overhead hoist transfer device configured to move along the second rail, wherein
the plurality of shelves are all arranged on one plane,
the carriers are configured to accommodate wafers,
the plurality of shelves, the first rail, the crane, and the transfer robot do not protrude beyond the sides of the columns in the second horizontal direction, and
an empty space is provided inside the lower support.

19. The distribution storage system of claim 18,
wherein the empty space extends from the floor to a first height in the vertical direction, and
the first height is in a range of about 2 m to about 2.5 m.

20. The distribution storage system of claim 18,
wherein the crane is connected to the transfer robot by a hoist, and
the transfer robot is configured to be driven in the vertical direction by the hoist.
